(19) United States
(12) Patent Application Publication
(10) Pub. No.: US 2011/0081503 A1
(43) Pub. Date: Apr. 7, 2011

(54) Method of depositing stable and adhesive interface between fluorine-based low-k material and metal barrier layer

(75) Inventors: Jianping ZHAO, Houston, TX (US); Lee CHEN, Cedar Creek, TX (US)

(73) Assignee: TOKYO ELECTRON LIMITED, Tokyo (JP)

(21) Appl. No.: 12/574,117

(22) Filed: Oct. 6, 2009

(51) Int. Cl. C23C 16/513; B05D 5/12; C23C 14/34; C23C 14/46

(52) U.S. Cl. 427/577; 427/97.1; 427/96.8; 204/192.1; 204/192.17; 204/192.38; 118/715; 204/298.02; 204/298.41; 118/723 R

(57) ABSTRACT

A method of integrating a fluorine-based dielectric with a metallization scheme is described. The method includes forming a fluorine-based dielectric layer on a substrate, forming a metal-containing layer on the substrate, and adding a buffer layer or modifying a composition of the fluorine-based dielectric layer proximate an interface between the fluorine-based dielectric layer and the metal-containing layer.

### CROSS-REFERENCE TO RELATED APPLICATIONS

This application is related to co-pending U.S. patent application Ser. No. ______, entitled “METHOD OF PROVIDING STABLE AND ADHESIVE INTERFACE BETWEEN FLUORINE-BASED LOW-K MATERIAL AND METAL BARRIER LAYER”, Docket No. TEA-048, filed on even date herewith. The entire content of this application is herein incorporated by reference in its entirety.

### BACKGROUND OF THE INVENTION

1. Field of the Invention

The invention relates to a method for preparing an interface for a fluorine-based low dielectric constant (low-k) material and, in particular, a method of integrating fluorine-based low-k materials with metal interconnects in semiconductor and electronic devices.

2. Description of Related Art

As the dimensions of ultra large scale integration (ULSI) circuits continuously shrink, the interconnect delay caused by parasitic capacitance becomes greater than the gate delay and, hence, dominates device performance with the current Al/SiO₂ metallization scheme. Significant research and development for using lower resistance metal (e.g., Cu) as well as lower capacitance interlayer dielectric (ILD) materials has been initiated and conducted for several decades. The use of low-k (low dielectric constant) dielectric materials not only reduces the line-to-line capacitance, but also minimizes cross-talk noise and reduces power consumption. A broad range of low-k materials, including fluorinated SiO₂, organic polymers or hybrid polymers, organosilicate glasses, nanoporous silica, and amorphous fluorocarbon have been investigated in detail. Moreover, the relevant properties, such as dielectric constant, thermal and mechanical stability, water and chemical resistance, adhesion, and gap fill capabilities, have been investigated.

Recent work on fluorine-based (alloyed, incorporated, or doped) low-k materials, such as CFₓ polymer or fluorinated amorphous carbon deposited by plasma enhanced chemical vapor deposition (PECVD) with a dielectric constant of 2.0-2.7, has shown that they are promising materials for interlayer dielectric applications. Further, it has been found that the electrical, thermal, and mechanical properties of these materials are dictated by the fluorine to carbon ratio in the corresponding deposited films. High fluorine content in these films leads to a lower dielectric constant, but poorer thermal and mechanical stability.

To accommodate Cu metallization, a barrier material, such as titanium, tungsten, or tantalum and their nitrides, is often used to be deposited under or on these fluorine-based low-k materials.

Currently, the main issue that has hindered the practical application of these fluorine-based low-k materials in ULSI is adhesion problems between fluorine-based low-k materials and metal barrier materials. Although there might be many other material or process related reasons that could cause the adhesion problem, the inventors believe that F atoms play a critical role in relation to the adhesion problem. The inventors recognize that F is a very reactive and corrosive element and, therefore, they suspect that F atoms, which initially existed at the interface between the metal barrier layer and the fluorine-based low-k materials or diffused from the bulk fluorine-based low-k materials and accumulated at the interface during device processing involving high temperature, may react with metal. Thus, the interface between the metal barrier layer and the fluorine-based low-k materials may become a very low strength corrosion layer and, consequently, may exhibit poor adhesion properties.

Whenever a metal barrier layer is deposited beneath or above these fluorine-based low-k materials, the metal element of the barrier layer may readily react with free and moveable F atoms in the fluorine-based low-k material to form metal fluoride which usually possesses a high vapor pressure and a high sensitivity to —OH groups. This interfacial chemical reaction process significantly weakens the interface strength, rendering a serious interface adhesion problem and, in time, a significant k-value increase due to penetration of water molecules. Furthermore, the metal layer acts like an F atom sink and, therefore, F atoms are expected to diffuse to a certain depth of the metal barrier layer. This diffusive process may reduce the ratio of F to C atoms in the fluorine-based low-k material and further cause the k-value to increase and become less stable.

### SUMMARY OF THE INVENTION

The invention relates to a method for preparing an interface for a fluorine-based low dielectric constant (low-k) material. Furthermore, the invention relates to a method of integrating fluorine-based low-k materials with metal interconnects in semiconductor and electronic devices.

According to an embodiment, a method of integrating a fluorine-based dielectric with a metallization scheme is described. The method comprises forming a fluorine-based dielectric layer on a substrate, forming a metal-containing layer on the substrate, and forming a buffer layer at an interface between the fluorine-based dielectric layer and the metal-containing layer, wherein the buffer layer includes a carbon-containing layer selected from the group consisting of tetrahedral amorphous carbon (ta-C), amorphous carbon (a-C), hydrogenated amorphous carbon (a-C:H), diamond-like carbon (DLC), nitrogenated amorphous carbon (a-C:N), carbon nitride (C₃N₄), amorphous carbon nitride (a-CN), hydrogenated amorphous carbon nitride (a-CN:H), or any combination of two or more thereof.

According to another embodiment, a method of integrating a fluorine-based dielectric with a metallization scheme is described. The method comprises forming a fluorine-based dielectric layer on a substrate, forming a metal-containing layer on the substrate, and forming a buffer layer at an interface between the fluorine-based dielectric layer and the metal-containing layer, wherein the metal buffer layer includes a metal selected from the group consisting of Ni, or Ni alloy, or both.

According to another embodiment, a method of integrating a fluorine-based dielectric with a metallization scheme is described. The method comprises forming CFₓ-based dielectric layer on a substrate, forming a metal-containing layer on the substrate, and forming a metal buffer layer at an interface between the fluorine-based dielectric layer and the metal-containing layer, wherein the metal buffer layer includes a metal selected from the group consisting of Al, Ni, Cu, Al alloy, Ni alloy, Cu alloy, or any combination of two or more thereof.

According to another embodiment, a platform for preparing a fluorine-based dielectric metallization scheme is described. The platform comprises a first film-forming system for forming a fluorine-based dielectric layer on a substrate, a second film-forming system for forming a metal-containing layer on the substrate, a third film-forming system for depositing a buffer layer between the fluorine-based dielectric layer and the metal-containing layer, and a transfer system coupled to the first film-forming system, the second film-forming system, and the treatment system, and configured to transfer a substrate there between.

### BRIEF DESCRIPTION OF THE DRAWINGS

In the accompanying drawings:

FIGS. 1A through 1D present a simplified schematic representation of a method of preparing an interface between a fluorine-based dielectric layer and a metal-containing layer according to an embodiment;

FIG. 2 illustrates a method of preparing an interface between a fluorine-based dielectric layer and a metal-containing layer according to another embodiment;

FIGS. 3A through 3E present a simplified schematic representation of a method of preparing an interface between a fluorine-based dielectric layer and a metal-containing layer in a metal interconnect according to an embodiment; and

FIG. 4 presents a schematic representation of a platform for preparing an interface between a fluorine-based dielectric layer and a metal-containing layer according to an embodiment.

### DETAILED DESCRIPTION OF EXEMPLARY EMBODIMENTS

A method and system for preparing an interface between a fluorine-based dielectric layer and a metal-containing layer is disclosed in various embodiments. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention.

Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” or variation thereof means that a particular feature, structure, material, or characteristic described in connection with the embodiment is included in at least one embodiment of the invention, but do not denote that they are present in every embodiment. Thus, the appearances of the phrases such as “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Nonetheless, it should be appreciated that, contained within the description are features which, notwithstanding the inventive nature of the general concepts being explained, are also of an inventive nature.

“Substrate” as used herein generically refers to the object being processed in accordance with the invention. The substrate may include any material portion or structure of a device, particularly a semiconductor or other electronics device, and may, for example, be a base substrate structure, such as a semiconductor wafer or a layer on or overlying a base substrate structure such as a thin film. Thus, substrate is not intended to be limited to any particular base structure, underlying layer or overlying layer, patterned or unpatterned, but rather, is contemplated to include any such layer or base structure, and any combination of layers and/or base structures. The description below may reference particular types of substrates, but this is for illustrative purposes only and not limitation.

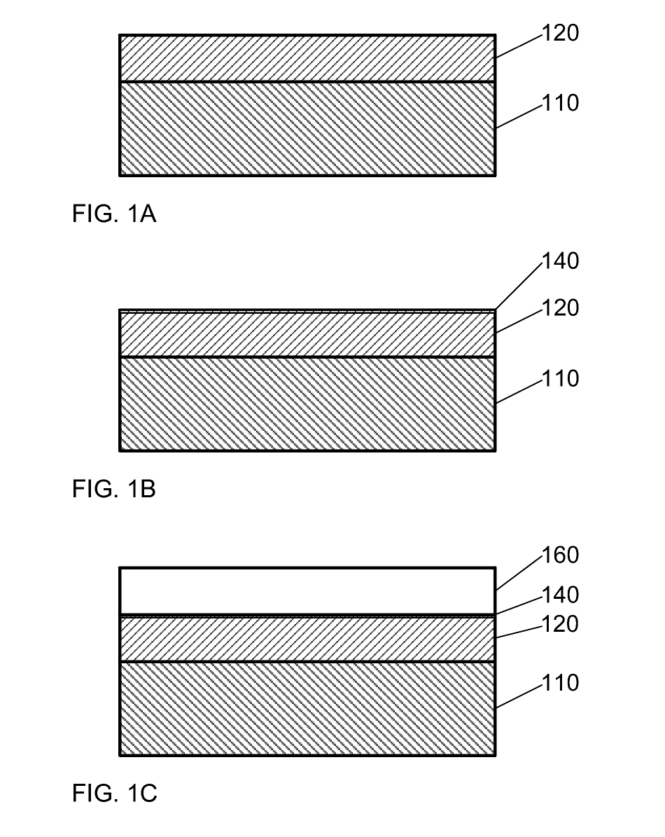

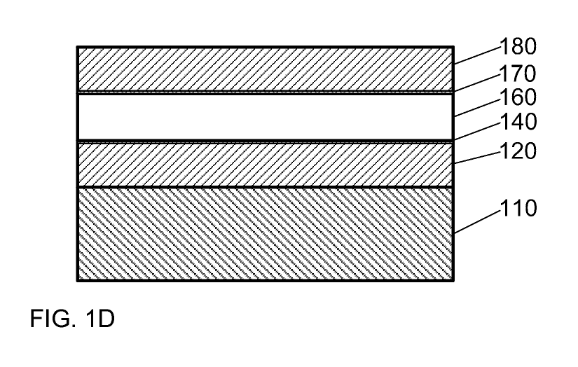

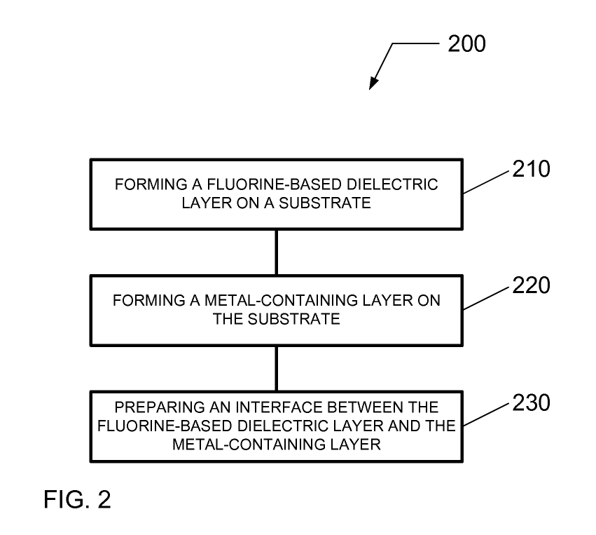

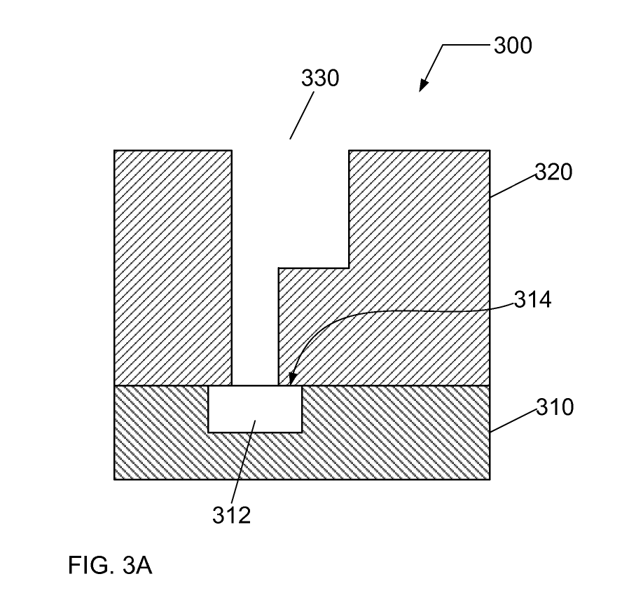

Referring now to the drawings, wherein like reference numerals designate identical or corresponding parts throughout the several views, FIGS. 1A through 1E, and FIG. 2 illustrate method for a preparing an interface between a fluorine-based dielectric layer and a metal-containing layer according to an embodiment. The method is illustrated in a flow chart 200, and begins in 210 with forming a fluorine-based dielectric layer 120 on substrate 110. The fluorine-based dielectric layer 120 may include a fluorine alloyed, a fluorine incorporated, or fluorine doped dielectric material. For example, the fluorine-based dielectric layer 120 may include a CFₓ-containing material, wherein x represents an integer greater than or equal to unity. Additionally, for example, the fluorine-based dielectric layer 120 may include a fluorinated amorphous carbon dielectric material.

The fluorine-based dielectric layer 120 may comprise a low dielectric constant (i.e., low-k) or ultra-low dielectric constant (i.e., ultra-low-k) dielectric layer having a nominal dielectric constant value less than the dielectric constant of SiO₂, which is approximately 4 (e.g., the dielectric constant for thermal silicon dioxide can range from 3.8 to 3.9). More specifically, the thin film may have a dielectric constant of less than 3.7, or a dielectric constant ranging from 1.6 to 3.7. Furthermore, the fluorine-based dielectric layer 120 may be non-porous or porous.

The fluorine-based dielectric layer 120 can be formed using a vapor deposition technique, such as chemical vapor deposition (CVD), plasma enhanced CVD (PECVD), atomic layer deposition (ALD), plasma enhanced ALD (PEALD), physical vapor deposition (PVD), or ionized PVD (iPVD), or a spin-on technique, such as those offered in the Clean Track ACT 8 SOD (spin-on dielectric), ACT 12 SOD, and Lithius coating systems commercially available from Tokyo Electron Limited (TEL). The Clean Track ACT 8 (200 mm), ACT 12 (300 mm), and Lithius (300 mm) coating systems provide coat, bake, and cure tools for SOD materials. The track system can be configured for processing substrate sizes of 100 mm, 200 mm, 300 mm, and greater. Other systems and methods for forming a thin film on a substrate are well known to those skilled in the art of both spin-on technology and vapor deposition technology.

In 220, a metal-containing layer 160 is formed on substrate 110. For example, the metal-containing layer 160 is formed on the fluorine-based dielectric layer 120 as shown in FIG. 1C. In one example, the metal-containing layer may include a metal layer, a metal seed layer, a metal wetting layer, a metal barrier layer, a metal adhesion layer, or any combination of two or more thereof. In another example, the metal-containing layer 160 may include a metal, a metal alloy, a metal oxide, a metal nitride, a metal oxynitride, a metal carbide, a metal silicide, or any combination of two or more thereof.

For example, the metal-containing layer 160 may include a copper (Cu)-containing material, an aluminum (Al)-containing material, a titanium (Ti)-containing material, a tantalum (Ta)-containing material, a tungsten (W)-containing layer, a rhenium (Re)-containing layer, a ruthenium (Ru)-containing layer, a rhodium (Rh)-containing layer, a palladium (Pd)-containing layer, or a silver (Ag)-containing layer, or any combination of two or more thereof. Additionally, for example, the metal-containing layer 160 may contain compounds of these metals and oxygen, nitrogen, carbon, boron, or phosphorus, or any combination of two or more thereof. Furthermore, for example, the metal-containing layer 160 may include Cu, Cu alloy, Al, Al alloy, Re, Ru, Rh, Pd, Ag, or any combination of two or more thereof. Further yet, for example, the metal-containing layer 160 may include W, Ti, Ta, oxides thereof, nitrides thereof, oxynitrides thereof, carbides thereof, silicides thereof, or any combination of two or more thereof.

The metal-containing layer 160 can be formed using a vapor deposition technique, such as chemical vapor deposition (CVD), plasma enhanced CVD (PECVD), atomic layer deposition (ALD), plasma enhanced ALD (PEALD), physical vapor deposition (PVD), or ionized PVD (iPVD), or any combination of two or more thereof.

In 230, an interface 140 is prepared between the fluorine-based dielectric layer 120 and the metal-containing layer 160. Thereafter, a dielectric layer 180 may be formed on the metal-containing layer 160, and a second interface 170 may be formed between the dielectric layer 180 and the metal-containing layer 160. The dielectric layer 180 may be the same material composition as the fluorine-based dielectric layer 120, or the dielectric layer 180 may be a different material composition than the fluorine-based dielectric layer 120. Additionally, the second interface 170 may be the same material composition as the interface 140, or the second interface 170 may be a different material composition as the interface 140. Additionally yet, the second interface 170 may be prepared in the same manner as the interface 140, or the second interface 170 may be prepared in a different manner than the interface 140. Furthermore, the interface 140 and/or the second interface 170 may be a fluorine (F) diffusion barrier layer.

As shown in FIGS. 1A through 1C, the interface (e.g., interface 140) may be prepared during and/or following the formation of the fluorine-based dielectric layer 120, and prior to the formation of the metal-containing layer 160. Alternatively and/or additionally, as shown in FIG. 1D, the interface (e.g., second interface 170) may be prepared following the formation of the metal-containing layer 160, and prior to and/or during the dielectric layer 180.

According to one embodiment, the preparation of an interface between a fluorine-based dielectric layer and a metal-containing layer comprises modifying a composition of the fluorine-based dielectric layer proximate an interface between the fluorine-based dielectric layer and the metal-containing layer. The modifying the composition of the fluorine-based dielectric layer may comprise increasing a relative concentration of carbon (C) near, at, or within the interface and/or reducing a relative concentration of fluorine (F) near, at, or within the interface.

According to another embodiment, the preparation of an interface between a fluorine-based dielectric layer and a metal-containing layer comprises modifying a composition of the fluorine-based dielectric layer proximate an interface between the fluorine-based dielectric layer and the metal-containing layer by irradiating the fluorine-based dielectric layer with non-plasma immersion, energetic charged particles. For example, the charged particles may include electrons, ions, or gas cluster ions, or any combination of two or more thereof. The flux of energetic charged particles may be collimated or not collimated. For example, the flux of energetic charged particles may be produced by an electron source, an ion source, or a gas cluster ion source, or any combination of two or more thereof. Additionally, for example, the flux of energetic charged particles may be produced by an electron beam source, an ion beam source, or a gas cluster ion beam source, or any combination of two or more thereof.

The irradiating the fluorine-based dielectric layer with non-plasma immersion, energetic charged particles may be performed in the same deposition system used for forming the fluorine-based dielectric layer on the substrate. Alternatively, the irradiating the fluorine-based dielectric layer with non-plasma immersion, energetic charged particles may be performed in a treatment system separate from the deposition system used for forming the fluorine-based dielectric layer on the substrate.

The irradiation of the fluorine-based dielectric layer by non-plasma immersion, energetic charged particles may modify the surface of the fluorine-based dielectric layer to form the interface, grow material at the surface of the fluorine-based dielectric layer to form the interface, deposit material at the surface of the fluorine-based dielectric layer to form the interface, dope the surface of the fluorine-based dielectric layer to form the interface, or infuse material at the surface of the fluorine-based dielectric layer to form the interface, or any combination of two or more thereof.

The irradiation of the fluorine-based dielectric layer by non-plasma immersion, energetic charged particles may be most suitable for when the metal-containing layer is deposited on top of the fluorine-based dielectric layer, as shown in FIG. 1C (e.g., metal-containing layer 160 is formed on top of the fluorine-based dielectric layer 120). Therein, high energy charged particles may form a C-rich surface either by hot electron dissociation or ion sputtering, for example. When a metal barrier layer, such as the metal-containing layer, is deposited on the fluorine-based dielectric layer, metal carbides would be formed at the interface and these carbides provide a very stable and adhesive interfacial layer.

According to another embodiment, the preparation of an interface between a fluorine-based dielectric layer and a metal-containing layer comprises modifying a composition of the fluorine-based dielectric layer proximate an interface between the fluorine-based dielectric layer and the metal-containing layer by adjusting a deposition process for the forming the fluorine-based dielectric layer.

The adjusting the deposition process for the forming the fluorine-based dielectric layer may comprise adjusting one or more of the following: (1) a plasma discharge condition for forming the fluorine-based dielectric layer; (2) a pressure for forming the fluorine-based dielectric layer; (3) a CF radical density; (4) a CF₂ radical density; (5) a CF₃ radical density; (6) a flow rate of a film-forming precursor; (7) a substrate temperature; or (8) a flow rate of a dilution gas; or (9) a combination of two or more thereof.

The film-forming precursor may include a CₓF_{y}-containing precursor, wherein x and y are integers greater than or equal to unity. Additionally, a dilution gas may be introduced with the film-forming precursor. The dilution gas may include a noble gas, such as argon (Ar), or a hydrogen-containing gas, such as H₂, or NH₃, or both.

The adjusting the plasma discharge condition for the deposition process may comprise adjusting a power coupled to an electrode supporting the substrate, or adjusting a power coupled to an electrode not supporting the substrate, or both.

The adjusting of the deposition process may be suitable for when the metal-containing layer is deposited on top of the fluorine-based dielectric layer, as shown in FIG. 1C (e.g., metal-containing layer 160 is formed on top of the fluorine-based dielectric layer 120), or when the fluorine-based dielectric layer is deposited on top of the metal-containing layer, as shown in FIG. 1D (e.g., dielectric layer 180 is formed on top of metal-containing layer 160). For example, if the fluorine-based dielectric layer is formed on the metal-containing layer, the modification of the surface to form an interface having C-rich material at the interface using non-plasma immersion, energetic charged particle irradiation is challenging and impractical.

By changing the fluorine-based dielectric layer deposition conditions, such as plasma discharge conditions, one or more adjustments may be made to grade the interface and produce a C-rich interface including, but not limited to: (i) increasing power coupled to the electrode supporting the substrate and/or the electrode not supporting the substrate; (ii) increasing bias power to the electrode supporting the substrate; (iii) increasing substrate temperature; (iv) increasing pressure; (v) increasing CF radical density; and/or (vi) decreasing CF₂ or CF₃ radical density. Therefore, the probability for bonding between an F atom and a metal atom may be lowered, and the total F atom to C atom ratio in the bulk materials may also be lowered. Alternately, the inventors suspect that diluting the film-forming precursor, i.e., a CₓFₓ precursor, with Ar and/or H₂ may also reduce the F atom to metal atom bonding possibility, and this result may not modify the dielectric constant of the fluorine-based dielectric layer.

According to another embodiment, the preparation of an interface between a fluorine-based dielectric layer and a metal-containing layer comprises modifying a composition of the fluorine-based dielectric layer proximate an interface between the fluorine-based dielectric layer and the metal-containing layer by exposing the fluorine-based dielectric layer to a nitrogen plasma excluding NH₃.

The nitrogen plasma may be formed using a gas comprising N₂, NO, N₂O, NO₂, or any combination of two or more thereof.

The use of a nitrogen plasma (e.g. formed using N₂, etc.) treatment of the fluorine-based dielectric layer may reduce F atoms on the surface and incorporate N atoms on the surface, which may improve the adhesion.

According to another embodiment, the preparation of an interface between a fluorine-based dielectric layer and a metal-containing layer comprises depositing a buffer layer at the interface between the fluorine-based dielectric layer and the metal-containing layer. The formation of the buffer layer may provide a stable and adhesive interface with the metal-containing layer and may also provide strong bonding with the fluorine-based dielectric layer. Desirably, the buffer layer should not significantly modify the k-value of the fluorine-based dielectric layer.

According to another embodiment, the depositing the buffer layer at the interface between the fluorine-based dielectric layer and the metal-containing layer comprises depositing a carbon-containing layer selected from the group consisting of tetrahedral amorphous carbon (ta-C), amorphous carbon (a-C), hydrogenated amorphous carbon (a-C:H), diamond-like carbon (DLC), nitrogenated amorphous carbon (a-C:N), carbon nitride (C₃N₄), amorphous carbon nitride (a-CN), hydrogenated amorphous carbon nitride (a-CN:H), or any combination of two or more thereof.

The buffer layer can be deposited using a vapor deposition technique, such as chemical vapor deposition (CVD), plasma enhanced CVD (PECVD), atomic layer deposition (ALD), plasma enhanced ALD (PEALD), physical vapor deposition (PVD), or ionized PVD (iPVD), or any combination of two or more thereof. For example, when plasma is used to enhance and/or facilitate the deposition of the buffer layer, plasma may be formed using capacitively coupled plasma (CCP), inductively coupled plasma (ICP), surface wave plasma, or radial line slot antenna (RLSA) plasma, or any combination of two or more thereof.

The buffer layer containing tetrahedral amorphous carbon (ta-C, or called amorphous diamond), or common amorphous carbon (a-C or a-C:H) or diamond-like carbon (DLC), or nitrogenated amorphous carbon (a-C:N), or carbon nitride (a-CN, a-CN:H, or C₃N₄) between the fluorine-based dielectric layer and the metal-containing layer may act as a chemical buffer layer between these two materially different layers. The buffer layer may lessen the reactivity or even block the reaction between the metal element of the metal-containing layer and F atoms in the fluorine-based dielectric layer. As a result, a metal carbide may be formed at the interface.

Additionally, a buffer layer containing, for example, amorphous carbon, may not significantly affect the k-value of the fluorine-based dielectric layer because a C—C bond (preferably sp³ hybridized) only has a slightly higher k-value than a C—F bond. Furthermore, a buffer layer containing, for example, a nitrogenated amorphous carbon (a-C:N) may also serve as the buffer layer. Nitrogenated amorphous carbon (a-C:N) may be deposited using plasma based CVD (e.g., PECVD via CCP, RLSA, etc.) through nitrogen plasma nitridation of an amorphous carbon layer. With optimal nitrogen plasma discharge conditions, substrate temperature, power, and pressure, only C—N single bonds may be obtained with C═N and C≡N bonds removed. Because a C—N bond has a shorter bond length than a C—C bond, the inventors expect a denser buffer layer may be formed that may further block the F atom reaction with metal-containing layer. In this context, highly sp³ bonded non-hydrogenated amorphous carbon (ta-C or amorphous diamond) deposited at room temperature using mono-energetic, low energy carbon ions produced by metal vacuum arc plasma (filtered or non-filtered) may be a superior candidate. Lower quality amorphous carbon based films may also be deposited by PVD or CVD methods such as broad ion beam assisted deposition.

According to another embodiment, the depositing the buffer layer at the interface between the fluorine-based dielectric layer and the metal-containing layer comprises depositing a metal selected from the group consisting of Al, Ni, Cu, Al alloy, Ni alloy, Cu alloy, or any combination of two or more thereof.

The buffer layer can be deposited using a vapor deposition technique, such as chemical vapor deposition (CVD), plasma enhanced CVD (PECVD), atomic layer deposition (ALD), plasma enhanced ALD (PEALD), physical vapor deposition (PVD), or ionized PVD (iPVD), or any combination of two or more thereof. For example, when plasma is used to enhance and/or facilitate the deposition of the buffer layer, plasma may be formed using capacitively coupled plasma (CCP), inductively coupled plasma (ICP), surface wave plasma, or radial line slot antenna (RLSA) plasma, or any combination of two or more thereof.

A buffer layer using a metal including Al, Ni, Cu, Ni—Cu alloy, such as MONEL®, etc., in contact with the fluorine-based dielectric layer may serve as a chemical buffer and/or Cu barrier layer. Depositing the above mentioned buffer layer on the top or the bottom of the fluorine-based dielectric layer may provide a stable (thermal and mechanical), non-volatile, adhesive, and/or low-k value metal fluoride at the interface. For example, Al fluoride (e.g. AlF₃) may or may not form at the interface after Al deposition in contact with the fluorine-based dielectric layer.

If Al fluoride is not formed, the buffer layer containing Al may provide a strong adhesive film that is stable at temperatures up to about 400° C. (about 650° C. for Ni; about 400° C. for Cu; about 550° C. for MONEL®; etc.). If Al fluoride is formed (such as at high temperature, high energy), the buffer layer containing Al fluoride may provide an adhesive interface between the fluorine-based dielectric layer and the metal-containing layer. A desirable feature for metal fluoride (e.g., Al fluoride) is a low k-value (e.g., about 2.2), which is closer to the k-value of the fluorine-based dielectric layer. In summary, metal fluorides possess good adhesion properties and a low k-value.

A buffer layer containing a metal fluoride is stable at temperatures exceeding about 1000° C. The buffer layer may be deposited by any evaporation, PVD (e.g., sputtering), or CVD/PECVD thin film deposition method. One example of Al CVD is the use of trimethyl aluminium (TMA) Al₂(CH₃)₆. Only a thin layer of Al is required for forming Al fluoride. Optionally or if desired, excess Al may be etched depending on the application. However, excess Al may be desirable since it may be converted to AlN by annealing in NH₃ or N₂, or by nitrogen plasma treatment. AlN provide a good copper diffusion barrier material and, thus, there may be no need for another metal or metal nitride barrier layer, such as TaN.

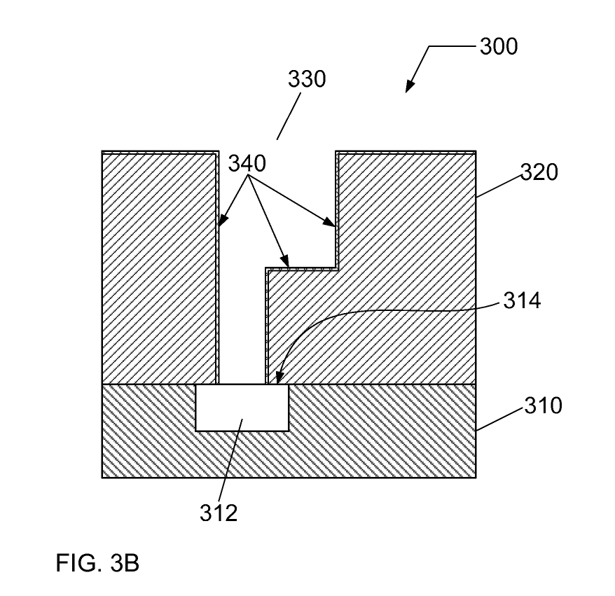

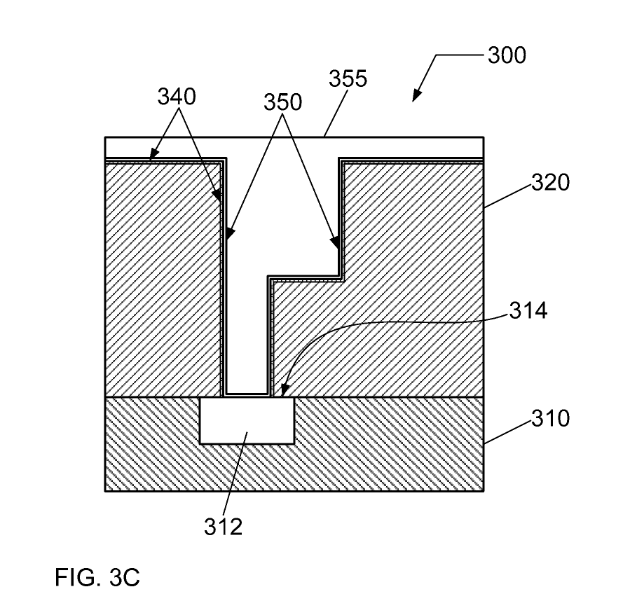

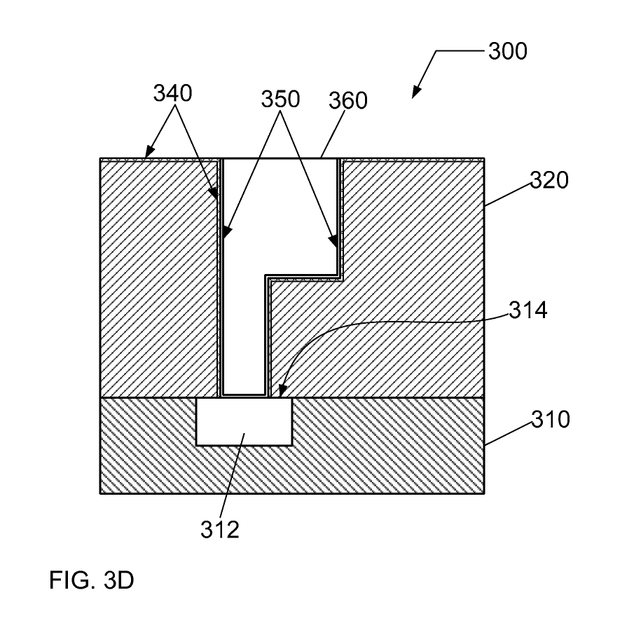

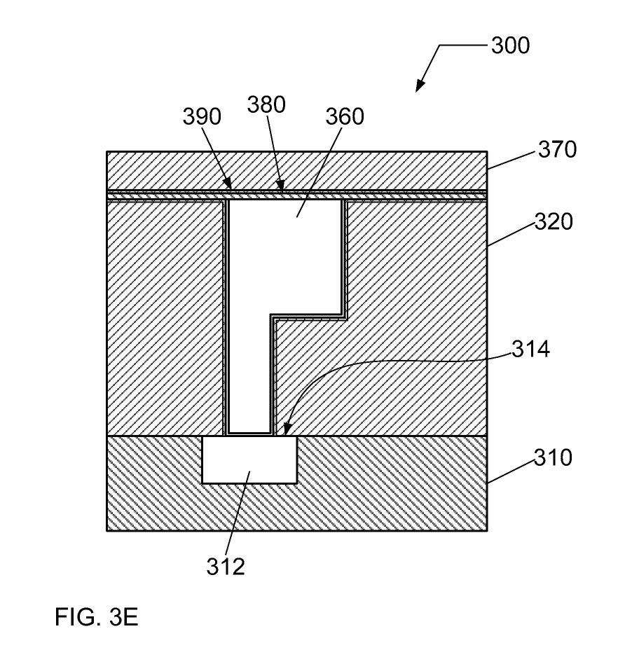

Turning now to FIGS. 3A through 3E, a simplified schematic representation of a method of preparing an interface between a fluorine-based dielectric layer and a metal-containing layer in a metal interconnect is provided according to an embodiment. As those skilled in the art will readily appreciate, embodiments of the invention can be applied to patterned substrates containing one or more vias, or trenches, or combinations thereof. FIG. 3A schematically illustrates a trench-via pattern 330 formed in an insulation layer 320, such as a fluorine-based dielectric layer as described above, on a substrate 310, wherein a metal line, to be formed in the trench of the trench-via pattern 330, is to make electrical and physical contact with another metal line 312 through a metal via, to be formed in the via portion of the trench-via pattern 330.

As illustrated in FIG. 3B, an interface 340 is prepared on a surface of the insulation layer 330. The interface 340 may be prepared using any one of the methods described above. For example, the interface 340 may serve as a F barrier layer for the insulation layer 330. Additionally, another interface may be prepared at boundary 314 between the insulation layer 330 and the underlying substrate 310.

As illustrated in FIG. 3C, the trench-via pattern 330 is lined with one or more conformal thin films 350. The one or more conformal thin films 350 may include a metal barrier layer, a metal adhesion layer, or a metal seed layer, or any combination of two or more thereof. Thereafter, the trench-via pattern 330 is filled with metal 355, such as Cu.

As illustrated in FIG. 3D, the trench-via pattern filled with metal 355 is planarized to form a planarized metal-filled trench-via structure 360. The planarization may be performed using chemical-mechanical planarization (CMP).

As illustrated in FIG. 3E, the planarized metal-filled trench-via structure 360 may be capped using one or more capping layers 380, and another insulation layer 370 may be formed thereon. Additionally, yet another interface 390 is prepared on a surface of the insulation layer 370. The interface 390 may be prepared using any one of the methods described above. For example, the interface 390 may serve as a F barrier layer for insulation layer 370.

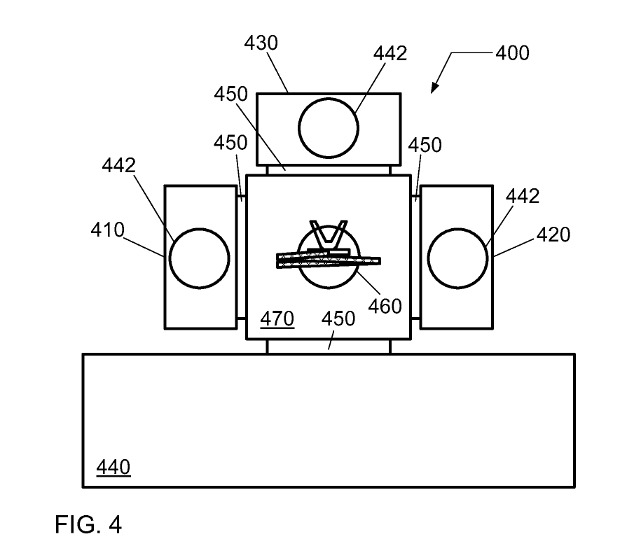

Turning now to FIG. 4, a top view of a platform 400 for processing a substrate and preparing a fluorine-based dielectric metallization scheme is provided according to yet another embodiment. The platform 400 comprises a first film-forming system 410 for forming a fluorine-based dielectric layer on a substrate 442, a second film-forming system 420 for forming a metal-containing layer on the substrate 442, a treatment system 430 for modifying a composition of the fluorine-based dielectric layer proximate an interface between the fluorine-based dielectric layer and the metal-containing layer, and a transfer system 470 coupled to the first film-forming system 410, the second film-forming system 420, and the treatment system 430, and configured to transfer a substrate there between. The treatment system 430 may include a radiation system, or a plasma processing system.

Alternatively, the treatment system 430 comprises a third film-forming system configured to deposit a buffer layer between the fluorine-based dielectric layer and the metal-containing layer. The third film-forming system may include a vapor deposition system, such as a physical vapor deposition (PVD) system, an ionized PVD system, a chemical vapor deposition (CVD) system, a plasma enhanced CVD system, an atomic layer deposition (ALD) system, or a plasma enhanced ALD system, or any combination of two or more thereof.

As illustrated in FIG. 4, the transfer system 470 is configured to transfer one or more substrates in and out of the first film-forming system 410, the second film-forming system 420, and the treatment system 430, and also to exchange one or more substrates with a multi-element manufacturing system 440. The multi-element manufacturing system 440 may comprise a load-lock element to allow cassettes of substrates to cycle between ambient conditions and low pressure conditions.

The transfer system 470 may comprise a dedicated handler 460 for moving one or more substrates between the first film-forming system 410, the second film-forming system 420, the treatment system 430, and the multi-element manufacturing system 440. In one embodiment, the multi-element manufacturing system 440 may permit the transfer of substrates to and from processing elements including such devices as etch systems, deposition systems, coating systems, patterning systems, metrology systems, etc.

In order to isolate the processes occurring in the first film-forming system 410, the second film-forming system 420, and the treatment system 430, an isolation assembly 450 is utilized to couple each system with the transfer system and the multi-element manufacturing system 440. For instance, the isolation assembly 450 may comprise at least one of a thermal insulation assembly to provide thermal isolation and a gate valve assembly to provide vacuum isolation. Of course, the first film-forming system 410, the second film-forming system 420, and the treatment system 430 may be placed in any sequence.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

What is claimed is:

1. A method of integrating a fluorine-based dielectric with a metallization scheme, comprising:
forming a fluorine-based dielectric layer on a substrate;
forming a metal-containing layer on said substrate; and
forming a buffer layer at an interface between said fluorine-based dielectric layer and said metal-containing layer, said buffer layer including a carbon-containing layer selected from the group consisting of tetrahedral amorphous carbon (ta-C), amorphous carbon (a-C), hydrogenated amorphous carbon (a-C:H), diamond-like carbon (DLC), nitrogenated amorphous carbon (a-C:N), carbon nitride (C₃N₄), amorphous carbon nitride (a-CN), hydrogenated amorphous carbon nitride (a-CN:H), or any combination of two or more thereof.

2. The method of claim 1, wherein said fluorine-based dielectric layer comprises a fluorine alloyed, a fluorine incorporated, or fluorine doped dielectric material.

3. The method of claim 1, wherein said fluorine-based dielectric layer comprises a CFₓ-containing material.

4. The method of claim 1, wherein said fluorine-based dielectric layer comprises a fluorinated amorphous carbon dielectric material.

5. The method of claim 1, further comprising:
forming a metal-barrier layer between said fluorine-based dielectric layer and said metal-containing layer.

6. The method of claim 1, wherein said buffer layer is formed using a vapor deposition process.

7. The method of claim 1, wherein said buffer layer is formed using a physical vapor deposition (PVD) process, an ionized PVD process, a chemical vapor deposition (CVD) process, a plasma enhanced CVD process, an atomic layer deposition (ALD) process, a plasma enhanced ALD process, a vacuum arc deposition (VAD) process, or a filtered VAD process, or any combination of two or more thereof.

8. The method of claim 7, wherein plasma is formed using capacitively coupled plasma (CCP), inductively coupled plasma (ICP), surface wave plasma, radial line slot antenna (RLSA) plasma, or a vacuum arc plasma, or any combination of two or more thereof.

9. A method of integrating a fluorine-based dielectric with a metallization scheme, comprising:
forming a fluorine-based dielectric layer on a substrate;
forming a metal-containing layer on said substrate; and
forming a buffer layer at an interface between said fluorine-based dielectric layer and said metal-containing layer, said metal buffer layer including a metal selected from the group consisting of Ni, or Ni alloy, or both.

10. The method of claim 9, wherein said fluorine-based dielectric layer comprises a fluorine alloyed, a fluorine incorporated, or fluorine doped dielectric material.

11. The method of claim 9, wherein said fluorine-based dielectric layer comprises a CFₓ-containing material.

12. The method of claim 9, wherein said fluorine-based dielectric layer comprises a fluorinated amorphous carbon dielectric material.

13. The method of claim 9, further comprising:
forming a metal-barrier layer between said fluorine-based dielectric layer and said metal-containing layer.

14. The method of claim 9, wherein said buffer layer is formed using a vapor deposition process.

15. The method of claim 9, wherein said buffer layer is formed using a physical vapor deposition (PVD) process, an ionized PVD process, a chemical vapor deposition (CVD) process, a plasma enhanced CVD process, an atomic layer deposition (ALD) process, a plasma enhanced ALD process, a vacuum arc deposition (VAD) process, or a filtered VAD process, or any combination of two or more thereof.

16. The method of claim 15, wherein plasma is formed using capacitively coupled plasma (CCP), inductively coupled plasma (ICP), surface wave plasma, radial line slot antenna (RLSA) plasma, or a vacuum arc plasma, or any combination of two or more thereof.

17. A method of integrating a fluorine-based dielectric with a metallization scheme, comprising:
forming CFₓ-based dielectric layer on a substrate;
forming a metal-containing layer on said substrate; and
forming a metal buffer layer at an interface between said fluorine-based dielectric layer and said metal-containing layer, said metal buffer layer including a metal selected from the group consisting of Al, Ni, Cu, Al alloy, Ni alloy, Cu alloy, or any combination of two or more thereof.

18. A platform for preparing a fluorine-based dielectric metallization scheme, comprising:
a first film-forming system for forming a fluorine-based dielectric layer on a substrate;
a second film-forming system for forming a metal-containing layer on said substrate;
a third film-forming system for depositing a buffer layer between said fluorine-based dielectric layer and said metal-containing layer, said buffer layer comprising a carbon-containing layer selected from the group consisting of tetrahedral amorphous carbon (ta-C), amorphous carbon (a-C), hydrogenated amorphous carbon (a-C:H), diamond-like carbon (DLC), nitrogenated amorphous carbon (a-C:N), carbon nitride (C₃N₄), amorphous carbon nitride (a-CN), hydrogenated amorphous carbon nitride (a-CN:H), or any combination of two or more thereof, or a metal selected from the group consisting of Ni, Ni alloy, Al, Al alloy, Cu, or Cu alloy, or both; and
a transfer system coupled to said first film-forming system, said second film-forming system and said third film-forming system, and configured to transfer a substrate there between.

19. The system of claim 18, wherein said third film-forming system comprises a vapor deposition system.

20. The system of claim 19, wherein said vapor deposition system comprises a physical vapor deposition (PVD) system, an ionized PVD system, a chemical vapor deposition (CVD) system, a plasma enhanced CVD system, an atomic layer deposition (ALD) system, a plasma enhanced ALD system, a vacuum arc deposition (VAD) process, or a filtered VAD process, or any combination of two or more thereof.
